(19) United States
(12) Patent Application Publication
(10) Pub. No.: US 2022/0209062 A1
(43) Pub. Date: Jun. 30, 2022

(54) Composite Substrate, Light Emitting Element, and Methods for Manufacturing Composite Substrate and Light Emitting Element

(71) Applicant: NGK INSULATORS, LTD., Aichi-prefecture (JP)

(72) Inventors: Masahiko Namerikawa, Nagoya-city (JP); Takashi Yoshino, Nagoya-city (JP); Yoshitaka Kuraoka, Nagoya-city (JP); Masahiro Sakai, Nagoya-city (JP)

(73) Assignee: NGK INSULATORS, LTD., Aichi-prefecture (JP)

(21) Appl. No.: 17/699,624

(22) Filed: Mar. 21, 2022

Related U.S. Application Data
(62) Division of application No. 15/223,099, filed on Jul. 29, 2016, now abandoned.
Application No. 15/223,099 is a continuation of application No. PCT/JP2015/050911, filed on Jan. 15, 2015.

(30) Foreign Application Priority Data
Feb. 7, 2014 (JP) 2014-022006

(51) Int. Cl. H01L 33/18; C30B 29/20; H01L 21/02; C30B 29/40; H01L 33/24; H01L 33/42

(52) U.S. Cl. CPC H01L 33/18; H01L 33/007; H01L 21/02576; H01L 21/02579; H01L 21/0243; H01L 21/0262; H01L 21/02458; H01L 21/02505; H01L 21/0254; H01L 21/0242; H01L 21/02488; C30B 29/406; H01L 33/24; H01L 33/42; C30B 29/20

(57) ABSTRACT

Provided are a light emitting device having a support layer having a surface with a three-dimensional shape, a light emitting functional layer formed on the surface with a three-dimensional shape of the support layer, and a translucent electrode layer provided on a side of the light emitting functional layer opposite to the support layer. The support layer functions as a reflective electrode, and a light emitting functional layer formed on the surface with a three-dimensional shape of the support layer. The light emitting functional layer has two or more layers composed of semiconductor single crystal grains. Each of the two or more layers has a single crystal structure in a direction approximately normal to the surface with a three-dimensional shape.

### CROSS-REFERENCE TO RELATED APPLICATIONS

This application is a divisional application of U.S. patent application Ser. No. 15/223,099, filed Jul. 29, 2016, which was a continuation application of PCT/JP2015/050911, filed Jan. 15, 2015, which claims priority to Japanese Patent Application No. 2014-022006 filed Feb. 7, 2014, the entire contents all of which are incorporated herein by reference.

### BACKGROUND OF THE INVENTION

### 1. Field of the Invention

The present invention relates to a composite substrate, a light emitting device, and manufacturing methods therefor.

### 2. Description of the Related Art

Light emitting diodes (LEDs) having various gallium nitride (GaN) layers on GaN single crystal and LEDs having various GaN layers on sapphire (α-alumina single crystal) are known as LEDs including single crystal substrates. For example, those LEDs are in mass production that have a structure formed by stacking an n-type GaN layer, a multiple quantum well (MQW) layer in which a quantum well layer composed of an InGaN layer and a barrier layer composed of a GaN layer are alternately stacked, and a p-type GaN layer in this order on a sapphire substrate. Moreover, a multi-layer substrate suitable for such use is also proposed. For example, Patent Document 1 (JP2012-184144A) discloses a gallium nitride crystal multi-layer substrate including a sapphire base substrate and a gallium nitride crystal layer formed by crystal growth on the substrate.

Meanwhile, laser CVD is a known technique for attaining highly oriented crystal growth. For example, Patent Document 2 (JP2004-107182A) discloses a film formation method comprising irradiating a substrate surface with a laser beam while introducing a raw material containing a gaseous material toward the substrate to form a film of the reaction product on the substrate surface through the heating of the substrate and the simultaneous reaction of the raw material. Patent Document 2 states that a film is obtained in which columnar crystals of yttria stabilized zirconia (YSZ) are oriented perpendicular to the substrate. Non-Patent Document 1 (Takashi Goto, “High-Speed Coating by Thermal and Laser CVD” SOKEIZAI, Vol. 51, 2010, No. 6, pp. 20-25) discloses YSZ coating and α-alumina coating by laser CVD. Non-Patent Document 2 (Akihiko Ito, “Highly-Oriented Crystal Growth by High-Speed Chemical Vapor Deposition in High-Intensity Laser Field”, Materia Japan, Vol 52, No. 11, 2013, pp. 525-529) discloses that selectively oriented crystal growth of α-alumina was promoted by laser CVD to obtain a c-axis oriented α-alumina film and, in particular, a film of highly oriented α-alumina having a coefficient of c-axis orientation of 90% can be rapidly synthesized on a polycrystalline AlN substrate.

### CITATION LIST

### Patent Documents

Patent Document 1: JP2012-184144A
Patent Document 2: JP2004-107182A

### Non-Patent Documents

Non-Patent Document 1: Takashi Goto, “High-Speed Coating by Thermal and Laser CVD” SOKEIZAI, Vol. 51, 2010, No. 6, pp. 20-25
Non-Patent Document 2: Akihiko Ito, “Highly-Oriented Crystal Growth by High-Speed Chemical Vapor Deposition in High-Intensity Laser Field”, Materia Japan, Vol 52, No. 11, 2013, pp. 525-529

### SUMMARY OF THE INVENTION

However, single crystal substrates as described above in general are small in area and expensive. Recently, there are demands for cost reduction in the manufacture of LEDs including large-area substrates, but the mass-production of large-area single crystal substrates is not easy and thus costly. Accordingly, an inexpensive material is desired that can be an alternative material for single crystal substrates such as sapphire and that is suitable for large-area substrates. In particular, commercially available single crystal substrates are flat, and it is thus difficult to manufacture light emitting devices having a three-dimensional shape such as a curved shape or a concave-convex shape with such a substrate.

The inventors have currently found that by forming a group 13 element nitride crystal layer on a substrate that has a surface with a three-dimensional shape composed of oriented polycrystalline alumina, it is possible to provide a composite substrate suitable for low-cost manufacture of light emitting devices having a three-dimensional shape, such as a curved shape or a concave-convex shape.

Accordingly, an object of the present invention is to provide a composite substrate suitable for low-cost manufacture of light emitting devices having a three-dimensional shape, such as a curved shape or a concave-convex shape, and a light emitting device having a three-dimensional shape manufactured with such a substrate.

According to an aspect of the present invention, there is provided a composite substrate comprising:
a substrate having a surface with a three-dimensional shape, wherein the surface with a three-dimensional shape comprises a layer composed of oriented polycrystalline alumina, or wherein an entirety of the substrate is composed of oriented polycrystalline alumina; and
a group 13 element nitride crystal layer formed on the oriented polycrystalline alumina of the substrate.

This composite substrate may further comprise a light emitting functional layer on the group 13 element nitride crystal layer.

According to another aspect of the present invention, there is provided a method for manufacturing a light emitting device, comprising the steps of:
forming a translucent electrode layer on the light emitting functional layer of the composite substrate of the present invention;
locally removing part of the light emitting functional layer before or after forming the translucent electrode layer to locally expose a lowermost layer of the light emitting functional layer; and
forming an electrode layer on the exposed lowermost layer to obtain the light emitting device.

According to yet another aspect of the present invention, there is provided a method for manufacturing a light emitting device, comprising the steps of:
forming a reflective electrode layer or a translucent electrode layer on the light emitting functional layer of the composite substrate of the present invention;
removing at least the substrate from the composite substrate before or after forming the reflective electrode layer or the translucent electrode layer to expose the light emitting functional layer, the group 13 element nitride crystal layer, or the seed crystal layer; and
forming a translucent electrode layer or a reflective electrode layer on the exposed light emitting functional layer, group 13 element nitride crystal layer, or seed crystal layer to obtain the light emitting device.

According to yet another aspect of the present invention, there is provided a method for manufacturing a light emitting device, comprising the steps of:
forming a support layer that also functions as a reflective electrode on the light emitting functional layer of the composite substrate of the present invention to obtain a reinforced composite substrate;
removing at least the substrate from the reinforced composite substrate to expose the light emitting functional layer, the group 13 element nitride crystal layer, or the seed crystal layer; and
forming a translucent electrode layer on the exposed light emitting functional layer, group 13 element nitride crystal layer, or seed crystal layer to obtain the light emitting device.

According to yet another aspect of the present invention, there is provided a method for manufacturing a light emitting device, comprising the steps of:
forming a temporary support layer on the light emitting functional layer of the composite substrate of the present invention to obtain a reinforced composite substrate;
removing at least the substrate from the reinforced composite substrate to expose the light emitting functional layer, the group 13 element nitride crystal layer, or the seed crystal layer;
forming a support layer that also functions as a reflective electrode on the exposed light emitting functional layer, group 13 element nitride crystal layer, or seed crystal layer to obtain a further reinforced composite substrate;
removing the temporary support layer from the further reinforced composite substrate to expose the light emitting functional layer; and
forming a translucent electrode layer on the exposed light emitting functional layer to obtain the light emitting device.

According to yet another aspect of the present invention, there is provided a light emitting device, comprising:
a support layer having a surface with a three-dimensional shape, wherein the support layer also functions as a reflective electrode;
a light emitting functional layer formed on the surface with a three-dimensional shape of the support layer, wherein the light emitting functional layer comprises two or more layers composed of semiconductor single crystal grains, wherein each of the two or more layers has a single crystal structure in a direction approximately normal to the surface with a three-dimensional shape; and
a translucent electrode layer provided on a side of the light emitting functional layer opposite to the support layer.

### BRIEF DESCRIPTION OF THE DRAWINGS

FIG. 1A is a schematic cross-sectional diagram showing one example of the composite substrate of the present invention. FIG. 1B shows an alternative embodiment in which the substrate 12 is a composite comprising a base substrate 12a and a layer 12b composed of oriented polycrystalline alumina on the base substrate 12a.

FIG. 2 is a schematic cross-sectional diagram showing one example of a horizontally-structured light emitting device produced with the composite substrate of the present invention.

FIG. 3 is a schematic cross-sectional diagram showing one example of a vertically-structured light emitting device produced with the composite substrate of the present invention.

FIG. 4 is a process diagram showing one example of the method for manufacturing a light emitting device of the present invention.

FIG. 5 is a process diagram showing another example of the method for manufacturing a light emitting device of the present invention.

FIG. 6 shows a perspective diagram of the substrate produced in Example 1 and a cross-sectional diagram taken along the line A-A′.

FIG. 7 is a perspective diagram showing the casting mold used in Example 1 for forming the substrate shown in FIG. 6.

FIG. 8 shows a perspective diagram of the substrate described as a modification in Example 1 and a cross-sectional diagram taken along the line B-B′.

FIG. 9 is a perspective diagram showing the casting mold for forming the substrate shown in FIG. 8 described as a modification in Example 1.

FIG. 10 is a diagram showing the graphite mold used in Example 4.

FIG. 11 is a diagram showing the graphite mold described as a modification in Example 4.

### DETAILED DESCRIPTION OF THE INVENTION

### Composite Substrate

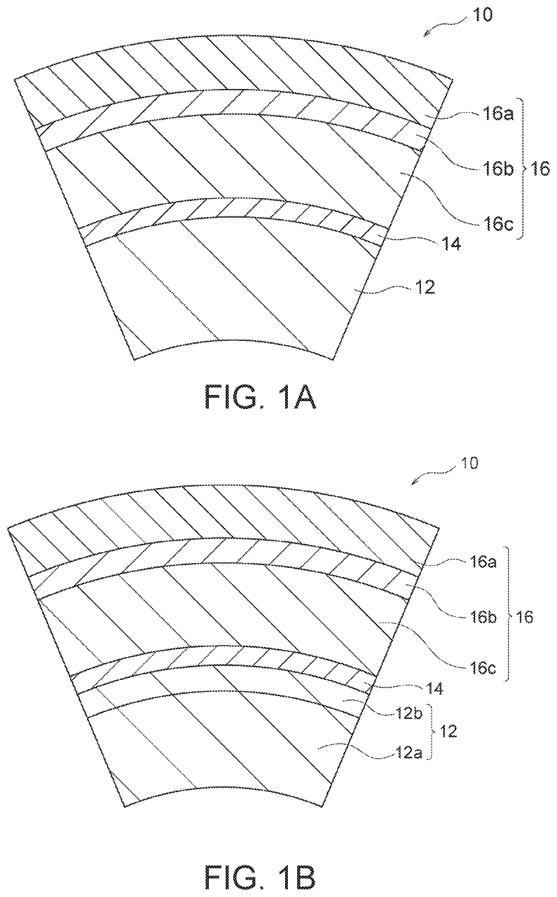

FIG. 1 schematically shows the layer configuration of a composite substrate according to one aspect of the present invention. A composite substrate 10 shown in FIG. 1 comprises a substrate 12 having a surface with a three-dimensional shape, a group 13 element nitride crystal layer 14 provided on the substrate 12, and optionally a light emitting functional layer 16 provided on the group 13 element nitride crystal layer 14. Therefore, the composite substrate 10 of the present invention may or may not have the light emitting functional layer 16. In an embodiment with the light emitting functional layer 16, a user can relatively easily produce a light emitting device, such as an LED, merely by performing suitable processing on the composite substrate 10 without forming the light emitting functional layer 16. On the other hand, in an embodiment without the light emitting functional layer 16, a user can produce a light emitting device, such as an LED, having desired light emitting characteristics by forming the light emitting functional layer 16 on the composite substrate 10 according to a desired configuration and technique, followed by performing suitable processing.

The substrate 12 is a substrate in which the surface having a three-dimensional shape comprises a layer composed of oriented polycrystalline alumina, or a substrate the entirety of which is composed of oriented polycrystalline alumina. In any case, the substrate has at least one surface that is composed of oriented polycrystalline alumina, and thus will be collectively referred to as an “oriented polycrystalline alumina substrate” or “substrate” below. The group 13 element nitride crystal layer 14 is formed on the oriented polycrystalline alumina of the substrate 12. The group 13 element nitride crystal layer 14 can provide a highly crystalline optimum base for forming the light emitting functional layer 16. In particular, the substrate 12 used in the present invention is not a sapphire substrate, which is an alumina single crystal widely used to date, but an oriented polycrystalline alumina substrate. Unlike single crystal substrates made of sapphire or the like that take an extended period of time to grow from seed crystals, the oriented polycrystalline alumina substrate can be efficiently manufactured through shaping and firing with an alumina powder or other raw material powders and optionally forming a film of an oriented alumina layer by laser CVD or the like. Therefore, not only can the oriented polycrystalline alumina substrate be manufactured at low cost but it can also have a desired three-dimensional shape such as a curved shape or a concave-convex shape due to ease in shaping, while being suitable for having a large area. In other words, not only can the oriented polycrystalline alumina substrate be produced or obtained at significantly lower cost and with a larger area than single crystal substrates made of sapphire or the like, but it can also have a desired three-dimensional shape. According to the inventors' findings, a composite substrate suitable for low-cost manufacture of light emitting devices having a desired three-dimensional shape such as a curved shape or a concave-convex shape can be provided by using the oriented polycrystalline alumina substrate 12 having a three-dimensional shape and forming the group 13 element nitride crystal layer 14 and optionally the light emitting functional layer 16 thereon. In this way, the composite substrate 10 of the present invention enables the manufacture of light emitting devices with an unprecedented breakthrough design, having a three-dimensional shape such as a curved shape or a concave-convex shape. For example, a light emitting device having a curved shape can converge emitted light in a specific direction or can disperse emitted light in multiple directions. Moreover, a light emitting device having a concave-convex shape can provide an increased light emitting area and thus an increased intensity of light emission.

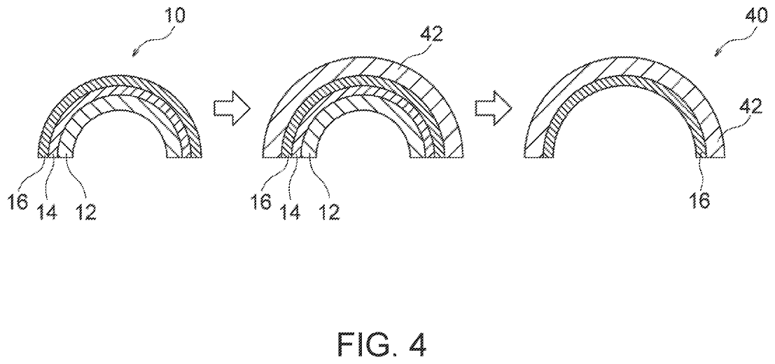

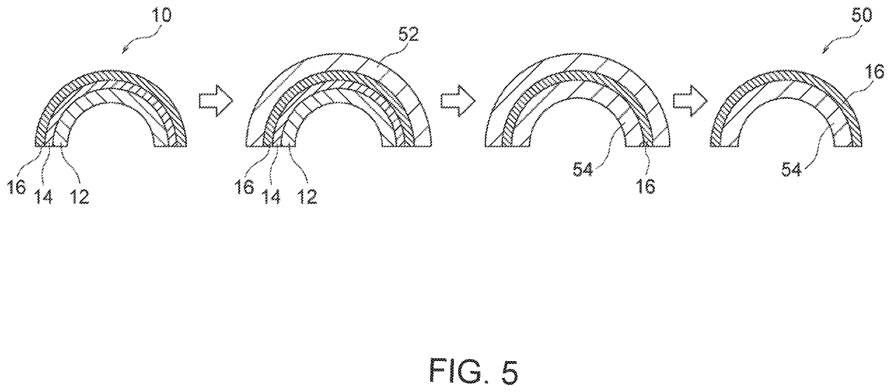

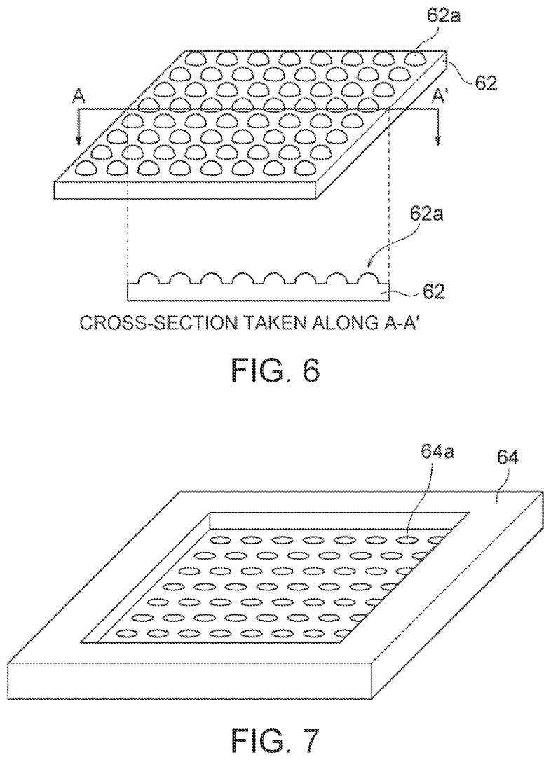

The substrate 12 has a surface with a three-dimensional shape. Specifically, at least the surface on which the group 13 element nitride crystal layer 14 is to be formed may have a three-dimensional shape, while other surfaces (e.g., the bottom surface on which the group 13 element nitride crystal layer 14 will not be formed) do not need to have a three-dimensional shape. Of course, the entire surface of the substrate 12 (i.e., the entirety of the substrate 12) may have a three-dimensional shape. The three-dimensional shape can be any solid shape except two-dimensional planar shapes. Preferable three-dimensional shape includes a curved shape and/or a concave-convex shape. The entirety of the substrate 12 may have a three-dimensional shape such as a curved shape and/or a concave-convex shape (see, e.g., FIGS. 4 and 5) or, in the alternative, the substrate 12 may partially have a planar portion, which leads to a combination of a planar shape and a three-dimensional shape (see, e.g., FIGS. 6 and 8). In any case, the surface of the substrate 12 on the side where the group 13 element nitride crystal layer 14 is to be formed desirably has such a shape that the three-dimensional shape is reflected in the light emitting device itself as a final product. Therefore, the three-dimensional shape is desirably a macroscopic shape having a visible, three-dimensional profile, and a three-dimensional microscopic shape as unrecognizable without a microscope would not be a desirable form because the three-dimensional shape is less likely to be reflected in the light emitting device itself as a final product. For reference, in the case of a flat-plate substrate having a concave-convex shape, the difference between the depth of concavities and the height of convexities is preferably 0.05 mm or greater, more preferably 0.1 mm or greater, and even more preferably 0.2 mm or greater, resulting in a sufficiently acceptable macroscopic shape having a visible, three-dimensional profile. Moreover, in the case of a substrate provided with concavities or convexities at a constant pitch, the number of concavities or convexities per 1 mm×1 mm area is preferably 4 or greater, more preferably 2 or greater, and even more preferably 1 or greater, resulting in a sufficiently acceptable macroscopic shape having a visible, three-dimensional profile. In order to take full advantage of the three-dimensional shape according to the present invention, a three-dimensional shape of a larger scale is preferable.

The substrate 12 has a surface with a three-dimensional shape, in which the surface comprises a layer composed of oriented polycrystalline alumina (hereinafter, oriented polycrystalline alumina layer), or the entirety of the substrate 12 is composed of oriented polycrystalline alumina. Alumina is aluminum oxide (Al₂O₃) and is typically α-alumina having the same corundum-type structure as single crystal sapphire, and the oriented polycrystalline alumina sintered body is a solid in which a countless number of alumina crystal grains in an oriented state are bonded to each other. Alumina crystal grains contain alumina and may contain a dopant and inevitable impurities as other elements, or may be composed of alumina and inevitable impurities. Although the oriented polycrystalline alumina layer or an oriented polycrystalline alumina body may also contain another phase or another element such as one described above in addition to alumina crystal grains, preferably the oriented polycrystalline alumina sintered body is composed of alumina crystal grains and inevitable impurities. The oriented plane of the oriented polycrystalline alumina layer or the oriented polycrystalline alumina body to be provided with a light emitting functional layer is not particularly limited and may be a c-plane, an a-plane, an r-plane, an m-plane, or the like. In any case, the use of the substrate 12 having oriented polycrystalline alumina makes it possible to achieve high luminous efficiency. In particular, when the group 13 element nitride crystal layer 14 and the constitutive layers of the light emitting functional layer 16 are formed on the oriented substrate 12 by way of epitaxial growth or crystal growth similar thereto, a state is achieved in which crystal orientation is mostly aligned in the direction approximately normal to the substrate, leading to attainment of a high luminous efficiency comparable to that attained with a single crystal substrate.

As described above, the crystal orientation direction in the oriented polycrystalline alumina is not particularly limited, and it may be the direction of a c-plane, an a-plane, an r-plane, an m-plane, or the like, and from the viewpoint of lattice constant matching, it is preferable that crystals are c-plane oriented in the case of using a group 13 element nitride based material such as a gallium nitride (GaN) based material or a zinc oxide based material for the light emitting functional layer. As for the degree of orientation, for example, the degree of orientation at the plate surface is preferably 50% or greater, more preferably 65% or greater, even more preferably 75% or greater, particularly preferably 85% or greater, particularly more preferably 90% or greater, and most preferably 95% or greater. The degree of orientation can be determined by obtaining an XRD profile through irradiating the plate surface of plate-shaped alumina with X-rays using an XRD apparatus (such as RINT-TTR III manufactured by Rigaku Corporation) and making a calculation according to the formulae below.

$$Degree of Orientation [ \% ] = \frac{p - {p}_{0}}{1 - {p}_{0}} \times 100 \\ {p}_{0} = \frac{{I}_{0} ( hkl )}{\sum {I}_{0} ( hkl )} \\ p = \frac{{I}_{s} ( hkl )}{\sum {I}_{s} ( hkl )} \qquad [ Mathematical Formula 1 ]$$

where I₀(hkl) and Iₛ(hkl) are the integral values)(2θ=20-70° of the diffraction intensities from the (hkl) planes in ICDD No. 461212 and a sample, respectively.

On the other hand, in the case where an unoriented polycrystalline alumina layer or an unoriented polycrystalline alumina sintered body is used for the substrate, grains with various crystal orientations undergo crystal growth in random directions when the group 13 element nitride crystal layer 14 and the constitutive layers of the light emitting functional layer 16 are formed. As a result, crystal phases mutually interfere, and it is thus not possible to create a state in which the crystal orientation is aligned in the direction approximately normal to the substrate. Moreover, since the rate of crystal growth is different depending on the crystal orientation, a homogenous, even light emitting functional layer cannot be formed, and it is thus difficult to form a light emitting functional layer of good quality.

The substrate 12 is preferably a composite comprising an oriented polycrystalline alumina layer 12b on a base substrate 12a, as shown in FIG. 1B, and is more preferably a c-plane oriented polycrystalline alumina layer. The base substrate may be an alumina-based sintered body, or may be an inorganic material such as another ceramic sintered body. The oriented polycrystalline alumina layer 12b can be desirably formed by laser CVD and/or lamp-heating CVD. The c-axis direction of the oriented polycrystalline alumina layer 12b obtained in this way is controllable by way of the conditions of film formation, and an increased supply of a raw material tends to result in c-plane orientation. In particular, laser CVD is preferable because with laser CVD the raw-material composition can be easily maintained, and a corundum-type crystal structure can be easily attained. According to the aforementioned techniques, it is possible to form an oriented polycrystalline alumina layer 12b after the production of the base substrate 12a. This enables the formation of the base substrate 12a with a high degree of freedom by, for example, using a casting mold having a desired shape, and thus makes it easy to provide the substrate 12 having a desired three-dimensional shape. The oriented polycrystalline alumina layer formed by laser CVD and/or lamp-heating CVD is composed of single crystal grains, wherein the layer has a single crystal structure in the direction approximately normal to the surface (in more strict sense, the tangential plane) of the base substrate having a three-dimensional shape, as reported in Patent Document 2 and Non-Patent Documents 1 and 2. That is, the oriented polycrystalline alumina layer 12b may have such a structure that grains are oriented in the direction of the tangential plane along the surface of the base substrate 12a. The thickness of the oriented polycrystalline alumina film is not particularly limited, and is preferably 0.1 to 100 μm.

The substrate 12 may be composed of an oriented polycrystalline alumina sintered body. The oriented polycrystalline alumina sintered body is composed of an alumina sintered body containing numerous alumina single crystal grains which are, to some extent or highly, oriented in a certain direction. The polycrystalline alumina sintered body oriented in this way is stronger and less expensive than alumina single crystals and, therefore, makes it possible to manufacture surface light emitting devices that are significantly less expensive and yet have a larger area than those manufactured when a single crystal substrate is used. In addition, as described above, the use of the oriented polycrystalline alumina sintered body makes it possible to achieve high luminous efficiency as well. In addition to ordinary pressureless sintering methods, pressure sintering methods such as hot isostatic pressing (HIP), hot pressing (HP), and spark plasma sintering (SPS), and combination thereof can be used for obtaining such an oriented polycrystalline sintered body, and a desired three-dimensional shape may be imparted at this time. For example, hot pressing (HP) performed using a mold (e.g., a graphite mold) having a desired three-dimensional shape makes it possible to obtain an oriented polycrystalline alumina sintered body having the corresponding desired three-dimensional shape.

The oriented polycrystalline alumina sintered body can be manufactured by forming and sintering, using a plate-shaped alumina powder as a raw material. A plate-shaped alumina powder is sold in the market and is commercially available. Preferably, a plate-shaped alumina powder can be formed into an oriented green body by a technique utilizing shearing force. Preferable examples of techniques utilizing shearing force include tape casting (such as a doctor blade method and a die coater method) and extrusion molding. In the orientation technique utilizing shearing force, it is preferable, in any technique exemplified above, that additives such as a binder, a plasticizer, a dispersing agent, and a dispersion medium are suitably added to the plate-shaped alumina powder to form a slurry, and the slurry is allowed to pass through a slit-shaped narrow discharge port to discharge the slurry to shape a sheet form on a substrate. The slit width of the discharge port is preferably 10 to 400 μm. The amount of the dispersion medium is adjusted so that the viscosity of the slurry is preferably 100 to 100000 cP and more preferably 500 to 60000 cP. The thickness of the oriented green body shaped into a sheet form is preferably 5 to 500 μm and more preferably 10 to 200 μm. It is preferable that numerous pieces of this oriented green body that has been shaped into a sheet form are stacked on top of the other to form a precursor laminate having a desired thickness, and pressing is performed on this precursor laminate. This pressing can be preferably performed by packing the precursor laminate in a vacuum pack or the like and subjecting it to isostatic pressing in hot water at 50 to 95° C. under a pressure of 10 to 2000 kgf/cm². Alternatively, it is also preferable that multiple pieces of a green body sheet, which are stacked one on top of the other, are allowed to pass between a pair of rollers warmed to 50° C. to 95° C. to continuously press-bond the sheet. Moreover, when extrusion molding is used, the flow channel within a metal mold may be designed so that after passing through a narrow discharge port within the metal mold, sheets of the green body are integrated into a single body within the metal mold, and the green body is ejected in a laminated state. It is preferable to degrease the resulting green body in accordance with known conditions. The oriented green body obtained in the above manner is fired by, in addition to ordinary pressureless firing, pressure sintering methods such as hot isostatic pressing (HIP), hot pressing (HP), and spark plasma sintering (SPS), and combination thereof, to form an alumina sintered body containing oriented alumina crystal grains. Although the firing temperature and the firing time in the above firing depend on the firing method, the firing temperature may be 1100 to 1900° C. and preferably 1500 to 1800° C., and the firing time may be 1 minute to 10 hours and preferably 30 minutes to 5 hours. Firing is more preferably performed through a first firing step of firing the green body in a hot press at 1500 to 1800° C. for 2 to 5 hours under a surface pressure of 100 to 200 kgf/cm², and a second firing step of re-firing the resulting sintered body with a hot isostatic press (HIP) at 1500 to 1800° C. for 30 minutes to 5 hours under a gas pressure of 1000 to 2000 kgf/cm². Although the firing time at the aforementioned firing temperature is not particularly limited, it is preferably 1 to 10 hours and more preferably 2 to 5 hours. A desired three-dimensional shape may be imparted to the green body in this first firing step. That is, hot pressing in a mold (e.g., a graphite mold) having a desired three-dimensional shape makes it possible to obtain an oriented polycrystalline alumina sintered body having the corresponding three-dimensional shape. The alumina sintered body obtained in this way is a polycrystalline alumina sintered body oriented in the direction of a desired plane such as a c-plane in accordance with the type of the aforementioned raw-material plate-shaped alumina powder. It is preferable to perform sandblasting or the like on the resulting oriented polycrystalline alumina sintered body to remove surface deposits, and then the surface is flattened by polishing-cloth processing involving diamond abrasive grains to provide an oriented polycrystalline alumina substrate.

The group 13 element nitride crystal layer 14 is formed on the oriented polycrystalline alumina of the substrate 12 and is composed of crystals of a group 13 element nitride. Preferably, the group 13 element nitride crystal layer 14 has a structure in which grains are grown mostly in conformity with the crystal orientation of the oriented polycrystalline alumina of the substrate 12. The group 13 element nitride crystal layer 14, which provides a highly crystalline optimum base for forming the light emitting functional layer 16, is a layer for reducing lattice defects resulting from a lattice mismatch that can occur between the substrate 12 and the light emitting functional layer 16 so as to improve crystallinity. When the degree of orientation of the polycrystalline alumina substrate 12 is low, the formation of the light emitting functional layer 16 directly on the substrate 12 cannot yield a homogenous, even light emitting functional layer, and pores may be formed in the light emitting functional layer. In this regard, the group 13 element nitride crystal layer 14 can improve their homogeneity and evenness and reduce or eliminate pores or the like, thereby enabling the formation of the light emitting functional layer 16 of good quality. The material of the group 13 element nitride crystal layer 14 is not particularly limited as long as it is based on a group 13 element nitride, and is preferably a gallium nitride (GaN) based material, an aluminum nitride (AlN) based material, and an indium nitride (InN) based material, and most preferably a gallium nitride (GaN) based material. Moreover, the material constituting the group 13 element nitride crystal layer 14 may be a mixed crystal in which AlN, InN, or the like forms a solid solution with GaN. Furthermore, the group 13 element nitride based material constituting the group 13 element nitride crystal layer 14 may be a non-doped material, or may suitably contain a dopant for controlling it to be a p-type or an n-type.

A seed crystal layer may be provided between the group 13 element nitride crystal layer 14 and the substrate 12. That is, it is preferable that the group 13 element nitride crystal layer 14 is formed in such a manner that a seed crystal layer is formed on the oriented alumina substrate, and then the group 13 element nitride crystal layer 14 and the light emitting functional layer 16 are formed. In this case, a seed crystal layer exists between the group 13 element nitride crystal layer 14 and the substrate 12.

The light emitting functional layer 16 has two or more layers composed of semiconductor single crystal grains wherein each of the layers has a single crystal structure in the direction approximately normal to the substrate, and can take a variety of known layer configurations that bring about light emission based on the principle of light emitting devices represented by LEDs by suitably providing an electrode and/or a phosphor and applying voltage. Therefore, the light emitting functional layer 16 may emit visible light such as blue or red, or may emit ultraviolet light with or without visible light. It is preferable that the light emitting functional layer 16 constitutes at least a part of a light emitting device that utilizes a p-n junction, and this p-n junction may include an active layer 16b between a p-type layer 16a and an n-type layer 16c as shown in FIG. 1. At this time, a double heterojunction or a single heterojunction (hereinafter collectively referred to as a heterojunction) may be used in which a layer having a smaller band gap than the p-type layer and/or the n-type layer is used as the active layer. Moreover, as one form of p-type layer/active layer/n-type layer, a quantum well structure can be adopted in which the thickness of the active layer is made small. Needless to say, in order to obtain a quantum well, a double heterojunction should be employed in which the band gap of the active layer is made smaller than those of the p-type layer and the n-type layer. Moreover, a multiple quantum well structure (MQW) may be used in which a large number of such quantum well structures are stacked. Adopting these structures makes it possible to increase luminous efficiency in comparison to a p-n junction. In this way, it is preferable that the light emitting functional layer 16 includes a p-n junction and/or a heterojunction and/or a quantum well junction, each of which has a light emitting function. Therefore, the two or more layers constituting the light emitting functional layer 16 can include two or more selected from the group consisting of an n-type layer doped with an n-type dopant, a p-type layer doped with a p-type dopant, and an active layer. The n-type layer, the p-type layer, and the active layer (if present) may be composed of materials whose main components are the same or mutually different.

As with the group 13 element nitride crystal layer 14, the layers constituting the light emitting functional layer 16 are each preferably composed of a group 13 element nitride based material, more preferably a gallium nitride (GaN) based material, an aluminum nitride (AlN) based material, and an indium nitride (InN) based material, and most preferably a gallium nitride (GaN) based material. For example, an n-type gallium nitride layer and a p-type gallium nitride layer may be grown on the group 13 element nitride crystal layer 14, or the order of stacking the p-type gallium nitride layer and the n-type gallium nitride layer may be inverse. Preferable examples of p-type dopants used for the p-type gallium nitride layer include one or more selected from the group consisting of beryllium (Be), magnesium (Mg), calcium (Ca), strontium (Sr), zinc (Zn), and cadmium (Cd). Preferable examples of n-type dopants used for the n-type gallium nitride layer include one or more selected from the group consisting of silicon (Si), germanium (Ge), tin (Sn), and oxygen (O). Moreover, the p-type gallium nitride layer and/or the n-type gallium nitride layer may be composed of gallium nitride formed into a mixed crystal with a crystal of one or more selected from the group consisting of AlN and InN, and the p-type layer and/or the n-type layer may be this mixed-crystal gallium nitride doped with a p-type dopant or an n-type dopant. For example, doping AlₓGa₁₋ₓN, which is a mixed crystal of gallium nitride and AlN, with Mg makes it possible to provide a p-type layer, and doping AlₓGa₁₋ₓN with Si makes it possible to provide an n-type layer. Forming gallium nitride into a mixed crystal with AlN widens the band gap and makes it possible to shift the emission wavelength toward the high energy side. Moreover, gallium nitride may be formed into a mixed crystal with InN, and this narrows the band gap and makes it possible to shift the emission wavelength toward the low energy side. Between the p-type gallium nitride layer and the n-type gallium nitride layer, there may be an active layer composed of GaN or a mixed crystal of GaN and one or more selected from the group consisting of AlN and InN, that has a smaller band gap than both layers. The active layer has a structure that forms a double heterojunction with a p-type layer and an n-type layer, and a configuration in which this active layer is made thin corresponds to the light emitting device having a quantum well structure, which is one form of a p-n junction, and luminous efficiency can be further increased. Moreover, the active layer may be configured to have a smaller band gap than either layer and be composed of GaN or a mixed crystal of GaN and one or more selected from the group consisting of AlN and InN. Luminous efficiency can be further increased also by such a single heterojunction.

The group 13 element nitride crystal layer 14 and the layers constituting the light emitting functional layer 16 each have a single crystal structure in the direction approximately normal to the surface of the substrate 12 and are each preferably composed of semiconductor single crystal grains. That is, each layer is composed of semiconductor single crystal grains connected in the direction of a tangential plane along the surface of the substrate 12, and, therefore, has a single crystal structure in the direction approximately normal to the substrate. Therefore, although the group 13 element nitride crystal layer 14 and the layers constituting the light emitting functional layer 16 are not a single crystal as a whole, they have a single crystal structure in terms of local domains, and can therefore have sufficiently high crystallinity for ensuring a light emitting function. Preferably, the group 13 element nitride crystal layer 14 and the layers constituting the light emitting functional layer 16 each have a structure in which grains are grown mostly in conformity with the crystal orientation of the oriented polycrystalline alumina constituting at least the surface of the substrate 12. The “structure in which grains are grown mostly in conformity with the crystal orientation of oriented polycrystalline alumina” means a structure resulting from crystal growth influenced by the crystal orientation of oriented polycrystalline alumina, is not necessarily limited to a structure in which grains are grown completely in conformity with the crystal orientation of oriented polycrystalline alumina, and may be a structure in which grains are grown, to some extent, in conformity with the crystal orientation of oriented polycrystalline alumina as long as desired light emitting functions can be ensured. That is, this structure also includes a structure in which grains are grown in crystal orientation different from that of oriented alumina. In this sense, the expression “structure in which grains are grown mostly in conformity with crystal orientation” can be paraphrased as “structure in which grains are grown in a manner mostly derived from crystal orientation”, and this paraphrasing and the above meaning similarly apply to similar expressions in this specification. Therefore, such crystal growth is preferably epitaxial growth, but it is not limited thereto, and may take a variety of similar crystal growth forms. In particular, when the layers respectively constituting the n-type layer, the active layer, the p-type layer, and the like grow in the same crystal orientation, the structure is such that the crystal orientation is mostly aligned with respect to the direction approximately normal to the substrate, and favorable light emitting properties can be obtained.

Therefore, the group 13 element nitride crystal layer 14 and the layers constituting the light emitting functional layer 16 are each observed as a single crystal when viewed in the direction normal to the substrate, and it is also possible to recognize the layers as aggregates of semiconductor single crystal grains having a columnar structure in which grain boundary is observed in a view of the cross section in the tangential plane direction of the substrate. Here, the “columnar structure” does not mean only a typical vertically long columnar shape, and is defined as having a meaning encompassing various shapes such as a horizontally long shape, a trapezoidal shape, and an inverted trapezoidal shape. As described above, each layer may have a structure in which grains are grown, to some extent, in conformity with the crystal orientation of oriented polycrystalline alumina, and does not necessarily need to have a columnar structure in a strict sense. As described above, the growth of single crystal grains due to the influence of the crystal orientation of oriented polycrystalline alumina, which is the substrate 12, is considered to be the cause of the columnar structure. Therefore, the average grain diameter at the cross section (hereinafter referred to as a cross-sectional average diameter) of semiconductor single crystal grains that can also be called columnar structures is considered to depend on not only the conditions of film formation but also the average grain diameter at the plate surface of oriented polycrystalline alumina. The interface of columnar structures constituting the light emitting functional layer influences luminous efficiency and emission wavelength, and the presence of grain boundaries impairs light transmittance in the cross-sectional direction and causes light to be scattered or reflected. Therefore, in the case of a structure from which light is extracted in the direction normal to the substrate, a luminance increasing effect due to scattered light from grain boundaries is also expected.

Crystallinity at the interface between columnar structures constituting the group 13 element nitride crystal layer 14 and the light emitting functional layer 16 is low, and therefore there is a possibility that the luminous efficiency deteriorates, the emission wavelength changes, and the emission wavelength broadens. Therefore, a larger cross-sectional average diameter of the columnar structures is more preferable. Preferably, the cross-sectional average diameter of the semiconductor single crystal grains at the outermost surface of the group 13 element nitride crystal layer 14 and the light emitting functional layer 16 is 0.3 μm or greater and more preferably 3 μm or greater. Although the upper limit of the cross-sectional average diameter is not particularly specified, the cross-sectional average diameter is realistically 1000 μm or less. In order to produce semiconductor single crystal grains having such a cross-sectional average diameter, it is desirable that, for example, the sintered grain diameter at the plate surface of alumina grains constituting oriented polycrystalline alumina, which serves as the substrate 12, is 0.3 μm to 1000 μm and more desirably 3 μm to 1000 μm.

The methods for producing the group 13 element nitride crystal layer 14, the light emitting functional layer 16, and the seed crystal layer are not particularly limited, and preferable are methods that promote crystal growth mostly in conformity with the crystal orientation of oriented polycrystalline alumina, which serves as the substrate 12. Metal organic chemical vapor deposition (MOCVD) is suitably used for producing the light emitting functional layer 16 and the seed crystal layer. Halide vapor phase epitaxy (HVPE), Na flux, ammonothermal method, and the like are suitably used for producing the group 13 element nitride crystal layer 14. For example, in the case where the light emitting functional layer 16 composed of a gallium-nitride-based material is produced with MOCVD, at least an organic metal gas containing gallium (Ga) (such as trimethylgallium) and a gas containing at least nitrogen (N) (such as ammonia) as raw materials may be flown over a substrate to allow growth in, for example, an atmosphere containing hydrogen, nitrogen, or both within a temperature range of about 300 to about 1200° C. In this case, film formation may be performed by suitably introducing an organic metal gas containing indium (In) or aluminum (Al) for band gap control as well as silicon (Si) or magnesium (Mg) as an n-type and p-type dopant (such as trimethylindium, trimethylaluminum, monosilane, disilane, and bis-cyclopentadienylmagnesium).

According to a particularly preferable aspect of the present invention, the composite substrate can be manufactured as follows. That is, (1) provide the oriented polycrystalline alumina substrate 12; (2) form a seed crystal layer composed of gallium nitride on the substrate 12 by MOCVD; (3) form the group 13 element nitride crystal layer 14 composed of gallium nitride on the seed crystal layer by Na flux; and optionally (4) form the light emitting functional layer 16 composed of a gallium-nitride-based material on the group 13 element nitride crystal layer 14. According to this procedure, a high-quality, gallium-nitride-based composite substrate 10 can be produced. A feature of this method is the formation of the group 13 element nitride crystal layer 14 by Na flux. The formation of the group 13 element nitride crystal layer 14 by Na flux is preferably performed by filling a crucible containing a seed crystal substrate with a melt composition containing metal Ga and metal Na and optionally a dopant, increasing the temperature and the pressure to 830 to 910° C. and 3.5 to 4.5 MPa, respectively, in a nitrogen atmosphere, and then rotating the crucible while retaining the temperature and the pressure. Although the retention time depends on the intended film thickness, it may be about 10 to about 20 hours. Moreover, it is preferable that the plate surface of gallium nitride crystals obtained by Na flux in this way is smoothed by lapping using diamond abrasive grains to provide the group 13 element nitride crystal layer 14.

Furthermore, an electrode layer and/or a phosphor layer may be provided on the light emitting functional layer 16. This makes it possible to provide a light emitting device composite material in a form that is closer to a light emitting device, enhancing the utility of the light emitting device composite material. The electrode layer, if provided, is preferably provided on the light emitting functional layer 16. The electrode layer may be composed of a known electrode material, and it is preferable to configure the electrode layer to be a transparent electroconductive film of ITO or the like or a metal electrode having a lattice structure, a mesh structure, a moth eye structure, or the like with a high level of light extraction efficiency because the efficiency of extracting light produced in the light emitting functional layer is increased.

When the light emitting functional layer 16 can emit ultraviolet light, a phosphor layer for converting ultraviolet light into visible light may be provided on the outer side of the electrode layer. The phosphor layer may be a layer containing a known fluorescent component capable of converting ultraviolet rays into visible light, and is not particularly limited. For example, preferable is such a configuration that a fluorescent component that becomes excited by ultraviolet light and emits blue light, a fluorescent component that becomes excited by ultraviolet light and emits blue to green light, and a fluorescent component that becomes excited by ultraviolet light and emits red light are allowed to be concomitantly present to obtain white light as a mixed color. Preferable combinations of such fluorescent components include (Ca,Sr)₅(PO₄)₃Cl:Eu, BaMgAl₁₀O₁₇:Eu and Mn, and Y₂O₃S:Eu, and it is preferable to disperse these components in a resin such as silicone resin to form a phosphor layer. Such fluorescent components are not limited to components exemplified above, and other ultraviolet-excited phosphors such as yttrium aluminum garnet (YAG), silicate phosphors, and oxynitride-based phosphors may be combined.

On the other hand, when the light emitting functional layer 16 can emit blue light, a phosphor layer for converting blue light into yellow light may be provided on the outer side of the electrode layer. The phosphor layer may be a layer containing a known fluorescent component capable of converting blue light into yellow light, and is not particularly limited. For example, it may be a combination with a phosphor that emits yellow light, such as YAG. Accordingly, a pseudo-white light source can be obtained because blue light that has passed through the phosphor layer and yellow light from the phosphor are complementary. The phosphor layer may be configured to perform both conversion of ultraviolet light into visible light and conversion of blue light into yellow light by including both a fluorescent component that converts blue into yellow and a fluorescent component that converts ultraviolet light into visible light.

Light Emitting Device

A light emitting device having a desired three-dimensional shape, such as a curved shape or a concave-convex shape can be produced with the above-described composite substrate of the present invention. Consequently, it is possible to manufacture light emitting devices with an unprecedented breakthrough design, having a three-dimensional shape. For example, a light emitting device having a curved shape can converge emitted light in a specific direction or can disperse emitted light in multiple directions. Moreover, a light emitting device having a concave-convex shape can provide an increased light emitting area and thus an increased intensity of light emission. Neither the structure of the light emitting device including the composite substrate of the present invention nor the production method therefor is particularly limited, and a user may perform suitable processing on the composite substrate to produce the light emitting device. Depending on the processing on the composite substrate, a horizontally-structured light emitting device as well as a vertically-structured light emitting device can be produced.

(1) Horizontally-Structured Light Emitting Device

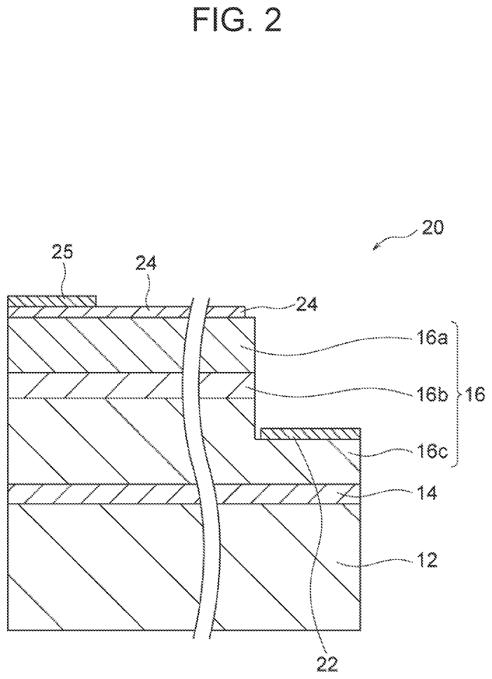

By using the composite substrate of the present invention, it is possible to produce a light emitting device with a so-called horizontal structure, in which an electric current flows not only in the direction normal to the light emitting functional layer 16 but also in the lateral direction. According to a preferable aspect of the present invention, such a horizontally-structured light emitting device can be produced by (a) forming a translucent electrode layer on the light emitting functional layer 16 of the composite substrate 10; (b) locally removing part of the light emitting functional layer 16 before or after (desirably after) forming the translucent electrode layer, to locally expose the lowermost layer of the light emitting functional layer 16 (e.g., an n-type layer or a p-type layer); and (c) forming an electrode layer on the exposed lowermost layer (e.g., an n-type layer or a p-type layer) to obtain the light emitting device. The translucent electrode layer is preferably a transparent electroconductive film of ITO or the like or a metal electrode having a lattice structure, a mesh structure, a moth eye structure, or the like with a high level of light extraction efficiency. FIG. 2 shows one example of a horizontally-structured light emitting device. The light emitting device 20 shown in FIG. 2 was produced with, as the composite substrate 10, a substrate having a planar edge for electrode formation (in FIG. 2, the curved portion is not shown for convenience of description). Specifically, a translucent anode 24 is provided on the top surface of the light emitting functional layer 16 (the top surface of the p-type layer 16a in the illustrated example) of the composite substrate 10, and optionally an anode pad 25 is provided on a part of the translucent anode 24. On the other hand, photolithography and etching (preferably reactive ion etching (RIE)) are performed on another part of the light emitting functional layer 16 to locally expose the n-type layer 16c, and a cathode 22 is provided on the exposed portion. In this way, the use of the composite substrate of the present invention makes it possible to produce a high-performance light emitting device merely by simple processing. As described above, an electrode layer and/or a phosphor layer may be provided on the composite substrate 10 in advance, and in such a case, a high-performance light emitting device can be produced through fewer steps.

(2) Vertically-Structured Light Emitting Device

Moreover, by using the composite substrate of the present invention, it is possible to produce a light emitting device with a so-called vertical structure, in which an electric current flows in the direction normal to the light emitting functional layer 16. The composite substrate 10 of the present invention includes insulating polycrystalline alumina for the substrate 12, and it is therefore not possible to provide an electrode on the substrate 12 side without modification, and is thus not possible to form a vertically-structured light emitting device. However, a vertically-structured light emitting device can be produced by removing the substrate 12 from the composite substrate 10. According to a preferable aspect of the present invention, such a vertically-structured light emitting device can be produced by (a) forming a reflective electrode layer or a translucent electrode layer on the light emitting functional layer 16 of the composite substrate 10; (b) removing at least the substrate 12 from the composite substrate 10 before or after (desirably after) forming the reflective layer or the translucent electrode layer, to expose the light emitting functional layer 16, the group 13 element nitride crystal layer 14, or the seed crystal layer; and (c) forming a translucent electrode layer or a reflective electrode layer on the exposed light emitting functional layer 16, group 13 element nitride crystal layer 14, or seed crystal layer to obtain the light emitting device. The translucent electrode layer is preferably a transparent electroconductive film of ITO or the like or a metal electrode having a lattice structure, a mesh structure, a moth eye structure, or the like with a high level of light extraction efficiency. A method for removing the substrate 12 from the composite substrate 10 is not particularly limited, and examples include grinding, chemical etching, interfacial heating by laser irradiation from the oriented sintered body side (laser lift-off), spontaneous separation utilizing a difference in thermal expansion induced by the temperature increase, and the like.

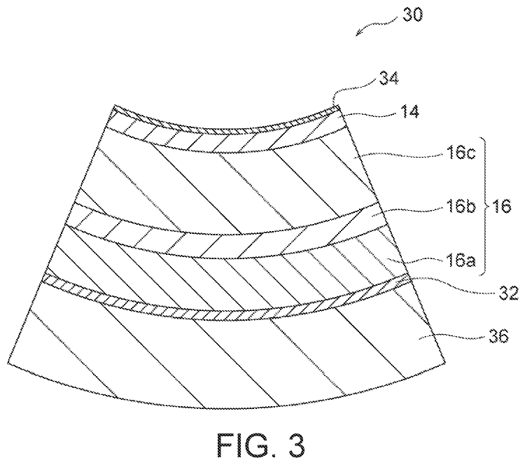

By removing the substrate 12 after joining the composite substrate 10 to a mounting substrate, a necessary level of strength required for the removal of the substrate 12 and subsequent steps can be ensured. FIG. 3 shows an example of a vertically-structured light emitting device produced in such a manner. FIG. 3 shows a light emitting device 30 produced with the composite substrate 10. Specifically, an anode layer 32 is provided in advance on the outermost surface of the composite substrate 10 as necessary (the surface of the p-type layer 16a in the illustrated example). Then, the anode layer 32 provided on the outermost surface of the light emitting functional layer 16 of the composite substrate 10 and a separately provided substrate 36 (hereinafter referred to as a mounting substrate 36) are joined. Then, the substrate 12 is removed by a known method such as grinding, laser lift-off, or etching. Finally, a cathode layer 34 is provided on the surface of the light emitting functional layer 16, the group 13 element nitride crystal layer 14, or the seed crystal layer exposed by removing the substrate 12. In the case of adopting such a structure, it is necessary to impart electrical conductivity to the light emitting functional layer 16, the group 13 element nitride crystal layer 14, or the seed crystal layer, for example, by doping it with a p-type or n-type dopant. In this way, it is possible to obtain the light emitting device 30 having the light emitting functional layer 16 formed on the mounting substrate 36. The type of the mounting substrate 36 is not particularly limited, and when the mounting substrate 36 is electrically conductive, it is also possible to create the light emitting device 30 having a vertical structure in which the mounting substrate 36 itself serves as an electrode. In this case, the mounting substrate 36 may be a semiconductor material doped with a p-type or n-type dopant or may be a metal material, as long as the light emitting functional layer 16 is not affected by diffusion or the like. The light emitting functional layer 16 may produce heat as it emits light. The temperature of the light emitting functional layer 16 and the surrounding part can be kept low when the mounting substrate 36 is made of a highly heat-conductive material.

By forming a support layer during the processing on the composite substrate 10, a necessary level of strength required for the removal of the substrate 12 and subsequent steps may be ensured. For example, as shown in FIG. 4, a light emitting device can be produced by (a) forming a support layer 42 that also functions as a reflective electrode on the light emitting functional layer 16 of the composite substrate 10 to obtain a reinforced composite substrate; (b) removing at least the substrate 12 from this reinforced composite substrate (the substrate 12 and the group 13 element nitride crystal layer 14 in FIG. 4) to expose the light emitting functional layer 16, the group 13 element nitride crystal layer 14, or the seed crystal layer (the light emitting functional layer 16 in FIG. 4); and (c) forming a translucent electrode layer on the exposed light emitting functional layer 16, group 13 element nitride crystal layer 14, or seed crystal layer to obtain the light emitting device. The material of the support layer 42 is not particularly limited as long as it is usable as a reflective electrode and can provide a level of strength required for a support when formed into a layer having a desired thickness. Examples of the material include Al, Ni, Ag, Pt, W, Mo, and the like. In the case of using GaN for the light emitting layer, W and Mo are preferable, which have a similar coefficient of thermal expansion and thus can suppress stress generated in the light emitting functional layer due to a temperature change. Preferably, as shown in FIG. 4, the composite substrate 10 has a curved shape, with the light emitting functional layer 16 being the outer circumferential surface, and, consequently the light emitting device is configured as a curved light emitting device 40 that emits light from the inner circumferential surface side. That is, the light emitting functional layer 16 is formed on the inner circumferential surface of the support layer 42, and accordingly the curved light emitting device 40 is configured to emit light from the inner circumferential surface side.

Alternatively, as shown in FIG. 5, the light emitting device may be produced by (a) forming a temporary support layer 52 on the light emitting functional layer 16 of the composite substrate 10 to obtain a reinforced composite substrate; (b) removing at least the substrate 12 (the substrate 12 and the group 13 element nitride crystal layer 14 in FIG. 5) from the reinforced composite substrate to expose the light emitting functional layer 16, the group 13 element nitride crystal layer 14, or the seed crystal layer (the light emitting functional layer 16 in FIG. 5); (c) forming a support layer 54 that also functions as a reflective electrode on the exposed light emitting functional layer 16, group 13 element nitride crystal layer 14, or seed crystal layer to obtain a further reinforced composite substrate; (d) removing the temporary support layer 52 from the further reinforced composite substrate to expose the light emitting functional layer 16; and (e) forming a translucent electrode layer (not shown) on the exposed light emitting functional layer 16 to obtain the light emitting device. The material of the temporary support layer 52 is not particularly limited as long as it can provide a level of strength required for a support when formed into a layer having a desired thickness and can be removed in the subsequent steps. Examples of the material include silica, polycrystalline silicon (polysilicon), photoresist, alumina, and the like. The material of the support layer 54 is not particularly limited as long as it is usable as a reflective electrode and can provide a level of strength required for a support when formed into a layer having a desired thickness. Examples of the material include Al, Ni, Ag, Pt, W, Mo, and the like. Preferably, as shown in FIG. 5, the composite substrate 10 has a curved shape, with the light emitting functional layer 16 being the outer circumferential surface, and, consequently the light emitting device is configured as a curved light emitting device 50 that emits light from the outer circumferential surface side. That is, the light emitting functional layer 16 is formed on the outer circumferential surface of the support layer 54, and accordingly the curved light emitting device 50 is configured to emit light from the outer circumferential surface side.

### EXAMPLES

The present invention will now be more specifically described by way of the following examples.

### Example 1

(1) Production of Substrate Having c-Axis Oriented Alumina Film

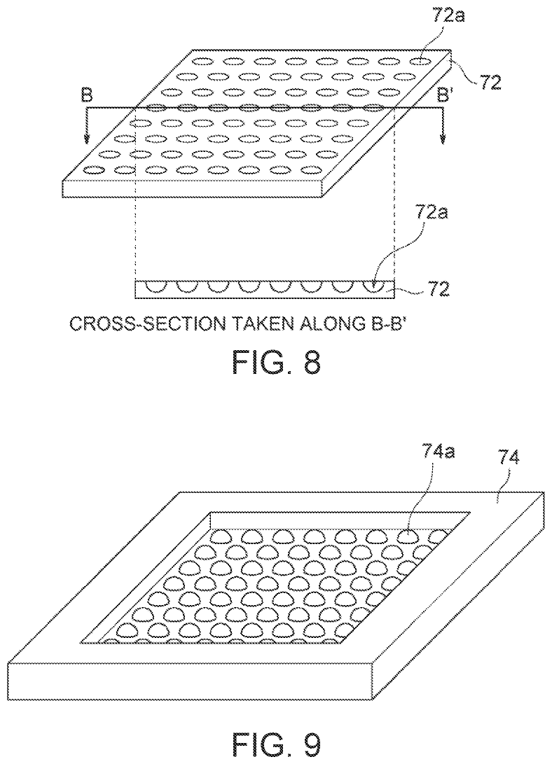

First, in order to produce a ceramic substrate 62 as shown in FIG. 6, a cast slurry was prepared by mixing 100 parts by weight of alumina powder and 0.025 parts by weight of magnesia as a raw material powder, 30 parts by weight of polybasic acid ester as a dispersion medium, 4 parts by weight of a diphenylmethane diisocyanate (MDI) resin as a gelling agent, 2 parts by weight of a dispersing agent, and 0.2 parts by weight of triethylamine as a catalyst. This cast slurry was poured at room temperature into an aluminium alloy casting mold 64 as shown in FIG. 7, then left to stand at room temperature for 1 hour to solidify, and released from the mold. Moreover, the released material was left to stand at room temperature and then 90° C. each for 2 hours to obtain a ceramic green body. This ceramic green body was calcined in air at 1200° C. and then fired in an atmosphere of hydrogen:nitrogen=3:1 at 1800° C. to become dense and translucent. As a result, a ceramic sintered body having convexities with a height of 0.3 mm at a pitch of 1 mm was obtained. Although the casting mold 64 patterned with concavities 64a as shown in FIG. 7 was used in this example to obtain the substrate 62 patterned with convexities 62a as shown in FIG. 6, a casting mold 74 patterned with convexities 74a as shown in FIG. 9 may be used to obtain a substrate 72 patterned with concavities 72a as shown in FIG. 8.

Next, the above ceramic sintered body having convexities was subjected to laser CVD to form a c-axis oriented alumina film thereon. Film formation by laser CVD was performed under conditions where the substrate temperature was 1170 K or higher, and an excess of aluminum tris(acetylacetonato) was used as an aluminum source. In this way, a ceramic sintered body substrate was obtained, the entire surface of which was coated with a 5 μm thick c-axis oriented alumina film.

(2) Production of Light Emitting Device Substrate

(2a) Formation of Seed Crystal Layer

Next, a seed crystal layer was formed on the c-axis oriented alumina film by MOCVD. Specifically, a 40 nm thick low-temperature GaN layer was deposited at 530° C., and then a GaN film having a thickness of 3 μm was laminated at 1050° C. to obtain a seed crystal substrate.

(2b) Formation of group 13 element nitride crystal layer by Na flux

The seed crystal substrate produced in the above process was placed in the bottom of a cylindrical, flat-bottomed alumina crucible having an inner diameter of 80 mm and a height of 45 mm, and then the crucible was filled with a melt composition in a glovebox. The composition of the melt composition is as follows.
Metal Ga: 60 g
Metal Na: 60 g

This alumina crucible was put in a vessel made of a refractory metal and sealed, and then placed on a rotatable rack of a crystal growth furnace. After the temperature and the pressure were increased to 870° C. and 4.0 MPa in a nitrogen atmosphere, the melt was maintained for 10 hours while being rotated and stirred, to allow gallium nitride crystals to grow as a group 13 element nitride crystal layer. After the end of crystal growth, the growth vessel was cooled slowly back to room temperature for 3 hours, and then the growth vessel was taken out from the crystal growth furnace. The melt composition remaining in the crucible was removed using ethanol, and a sample in which gallium nitride crystals grew was recovered. In the resulting sample, gallium nitride crystals grew on the entire surface of the 50.8 mm (2 inches) seed crystal substrate, and the crystal thickness was about 0.1 mm. No cracks were observed.

The resulting oriented alumina substrate was fixed to a ceramic surface plate, the plate surface of gallium nitride crystals of the oriented alumina substrate was smoothed by lapping using diamond abrasive grains. At this time, flatness was improved by reducing the size of abrasive grains from 10 μm to 0.1 μm in a stepwise manner. The average roughness Ra at the plate surface of gallium nitride crystals after processing was 0.2 nm. In this way, a substrate was obtained in which a gallium nitride crystal layer having a thickness of about 50 μm was formed on an oriented alumina substrate.

(2c) Formation of Light Emitting Functional Layer by MOCVD and Determination of Cross-Sectional Average Diameter

A 3 μm thick n-GaN layer doped to have a Si atom concentration of 5×10¹⁸/cm³ was deposited at 1050° C. as an n-type conductive layer on the substrate by MOCVD. Next, a multiple quantum well layer was deposited at 750° C. as an active layer. Specifically, five 2.5 nm thick InGaN well layers and six 10 nm thick GaN barrier layers were alternately stacked. Next, a 200 nm thick p-GaN doped to have a Mg atom concentration of 1×10¹⁹/cm³ was deposited at 950° C. as a p-type conductive layer. Thereafter, the sample was taken out from the MOCVD apparatus, 800° C. heat treatment was performed for 10 minutes in a nitrogen atmosphere as activation treatment of Mg ions of the p-type conductive layer, and thus a light emitting device substrate was obtained.

(3) Production and Evaluation of Horizontally-Structured Light Emitting Device

A part of the n-type conductive layer was exposed by performing photolithography and RIE on the light emitting functional layer side of the produced light emitting device substrate. Subsequently, Ti/Al/Ni/Au films as a cathode were patterned on the exposed portion of the n-type conductive layer in a thickness of 15 nm, 70 nm, 12 nm, and 60 nm, respectively, by photolithography and vacuum deposition. Thereafter, to improve ohmic contact characteristics, 700° C. heat treatment was performed in a nitrogen atmosphere for 30 seconds. Furthermore, Ni/Au films were patterned as a translucent anode on the p-type conductive layer in a thickness of 6 nm and 12 nm, respectively, by photolithography and vacuum deposition. Thereafter, to improve ohmic contact characteristics, 500° C. heat treatment was performed in a nitrogen atmosphere for 30 seconds. Furthermore, Ni/Au films that served as an anode pad were patterned in a thickness of 5 nm and 60 nm, respectively, on a partial area of the top surface of the Ni/Au films as a translucent anode by photolithography and vacuum deposition. The wafer obtained in this way was cut into a chip and, further, furnished with a lead frame to provide a horizontally-structured light emitting device.

(Evaluation of Light Emitting Device)

When electricity was applied across the cathode and the anode, and I-V measurement was performed, rectifying characteristics were confirmed. Moreover, with an electric current flowing in the forward direction, emission of light having a wavelength of 450 nm was confirmed.

### Example 2

(1) Production of Light Emitting Device Substrate

(1a) Formation of Group 13 Element Nitride Crystal Layer by Na Flux

A seed crystal substrate having a 3 μm thick GaN film stacked on an oriented alumina substrate was produced as in Example 1. A group 13 element nitride crystal layer was formed on this seed crystal substrate as in (2b) of Example 1 except that the composition of the melt composition was as follows.
Metal Ga: 60 g
Metal Na: 60 g
Germanium tetrachloride: 1.85 g

In the resulting sample, germanium-doped gallium nitride crystals grew on the entire surface of the 50.8 mm (2 inches) seed crystal substrate, and the crystal thickness was about 0.1 mm. No cracks were observed. Then, the sample was processed by the same method as (2b) of Example 1 to provide a substrate in which a germanium-doped gallium nitride crystal layer having a thickness of about 50 μm was formed as a group 13 element nitride crystal layer on an oriented alumina film.

(Determination of Volume Resistivity)

The in-plane volume resistivity of the germanium-doped gallium nitride crystal layer was measured using a Hall effect analyzer. As a result, the volume resistivity was 1×10⁻² Ω·cm.

(1b) Formation of Light Emitting Functional Layer by MOCVD and Determination of Cross-Sectional Average Diameter

By a method similar to (2c) of Example 1, a light emitting functional layer was formed on the substrate, and a light emitting device substrate was thus obtained.

(2) Production and Evaluation of Vertically-Structured Light Emitting Device

The light emitting device substrate produced in this example was subjected to vacuum deposition to deposit a 200 nm thick Ag film as a reflective anode layer on the p-type conductive layer, followed by heat treatment at 500° C. in a nitrogen atmosphere for 30 seconds to improve ohmic contact characteristics. Next, the substrate was irradiated with an excimer laser having a wavelength of 248 nm from the polycrystalline alumina substrate side to thermally decompose GaN in the vicinity of the polycrystalline alumina substrate, then the wafer was cooled to 30° C. to separate GaN from the polycrystalline alumina substrate, and thereby the group 13 element nitride crystal layer composed of germanium-doped gallium nitride was exposed. Ti/Al/Ni/Au films as a cathode were then patterned on the group 13 element nitride crystal layer in a thickness of 15 nm, 70 nm, 12 nm, and 60 nm, respectively, by photolithography and vacuum deposition. The cathode was patterned into a shape having an opening so that light can be extracted from a portion where the electrode was not formed. Thereafter, to improve ohmic contact characteristics, 700° C. heat treatment was performed in a nitrogen atmosphere for 30 seconds. The wafer obtained in this way was cut into a chip and, further, furnished with a lead frame to provide a vertically-structured light emitting device.

(Evaluation of Light Emitting Device)

When electricity was applied across the cathode and the anode, and I-V measurement was performed, rectifying characteristics were confirmed. Moreover, with an electric current flowing in the forward direction, emission of light having a wavelength of 450 nm was confirmed.

### Example 3

(1) Production of Light Emitting Device Substrate

(1a) Formation of Group 13 Element Nitride Crystal Layer by Na Flux

A seed crystal substrate having a 3 μm thick GaN film stacked on an oriented alumina substrate was produced as in Examples 1 and 2. A group 13 element nitride crystal layer was formed on this seed crystal substrate as in (2b) of Example 1 except that the composition of the melt composition was as follows.
Metal Ga: 60 g
Metal Na: 60 g
Germanium tetrachloride: 1.85 g

In the resulting sample, germanium-doped gallium nitride crystals grew on the entire surface of the 50.8 mm (2 inches) seed crystal substrate, and the crystal thickness was about 0.1 mm. No cracks were observed. Then, the sample was processed by the same method as (2b) of Example 1 to provide a substrate in which a germanium-doped gallium nitride crystal layer having a thickness of about 50 μm was formed as a group 13 element nitride crystal layer on an oriented alumina film.

(Determination of Volume Resistivity)

The in-plane volume resistivity of the germanium-doped gallium nitride crystal layer was measured using a Hall effect analyzer. As a result, the volume resistivity was 1×10⁻² Ω·cm.

(1b) Formation of Light Emitting Functional Layer by MOCVD and Determination of Cross-Sectional Average Diameter

By a method similar to (2c) of Example 1, a light emitting functional layer was formed on the substrate, and a light emitting device substrate was thus obtained.

(2) Production and Evaluation of Vertically-Structured Light Emitting Device

A polycrystalline alumina support member was formed by laser CVD as a temporary support layer on the light emitting functional layer of the light emitting device substrate produced in this example. Next, the substrate was irradiated with an excimer laser having a wavelength of 248 nm from the polycrystalline alumina substrate, i.e., base substrate, side to thermally decompose GaN in the vicinity of the polycrystalline alumina substrate, then the wafer was cooled to 30° C. to separate the laminate of temporary support layer/light emitting functional layer/group 13 element nitride crystal layer from the polycrystalline alumina substrate. In this way, the group 13 element nitride crystal layer composed of germanium-doped gallium nitride was exposed. A 100 μm thick tungsten (W) film was deposited as a reflective cathode layer on the exposed group 13 element nitride crystal layer. Next, the substrate was irradiated with an excimer laser having a wavelength of 248 nm from the side where the above alumina support member was formed by laser CVD to thermally decompose GaN in the vicinity of the alumina support member (the temporary support layer) and remove the temporary support layer to expose the light emitting functional layer (more specifically, the p-type conductive layer). Next, Ti/Al/Ni/Au films as an anode were patterned on the exposed light emitting layer (more specifically, the p-type conductive layer) in a thickness of 15 nm, 70 nm, 12 nm, and 60 nm, respectively, by photolithography and vacuum deposition. The anode was patterned into a shape having an opening so that light can be extracted from a portion where the electrode was not formed. Thereafter, to improve ohmic contact characteristics, 700° C. heat treatment was performed in a nitrogen atmosphere for 30 seconds. The wafer obtained in this way was cut into a chip and, further, furnished with a lead frame to provide a vertically-structured light emitting device.

(Evaluation of Light Emitting Device)

When electricity was applied across the cathode and the anode, and I-V measurement was performed, rectifying characteristics were confirmed. Moreover, with an electric current flowing in the forward direction, emission of light having a wavelength of 450 nm was confirmed.

### Example 4: Another Production Example of c-Axis Oriented Polycrystalline Alumina Substrate

As a raw material, a plate-shaped alumina powder (manufactured by Kinsei Matec Co., Ltd., grade 00610) was provided. 7 parts by weight of a binder (polyvinyl butyral: lot number BM-2, manufactured by Sekisui Chemical Co., Ltd.), 3.5 parts by weight of a plasticizer (DOP: di(2-ethylhexyl) phthalate, manufactured by Kurogane Kasei Co., Ltd.), 2 parts by weight of a dispersing agent (Rheodol SP-030, manufactured by Kao Corporation), and a dispersion medium (2-ethylhexanol) were mixed with 100 parts by weight of the plate-shaped alumina particles. The amount of the dispersion medium was adjusted so that the slurry viscosity was 20000 cP. The slurry prepared as above was shaped into a sheet form on a PET film by a doctor blade method so as to have a dry thickness of 20 μm. The resulting tape was cut into circles having a diameter of 100 mm, then 150 pieces were stacked and placed on an Al plate having a thickness of 10 mm, and then vacuum packing was performed. This vacuum pack was subjected to isostatic pressing in hot water at 85° C. under a pressure of 100 kgf/cm², and a green body was obtained.

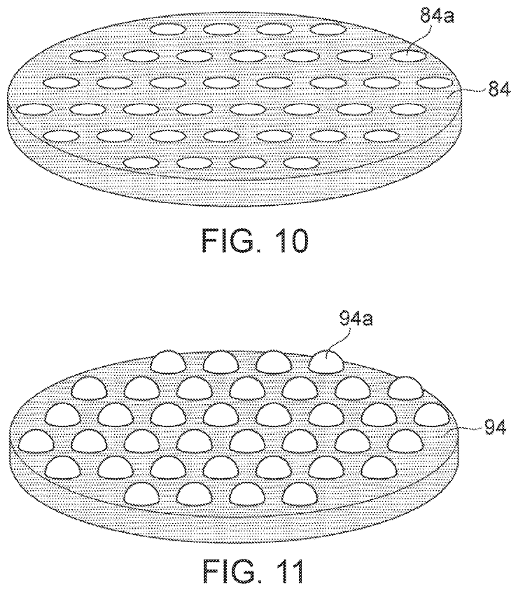

The resulting green body was placed in a degreasing furnace and degreased at 600° C. for 10 hours. The resulting degreased body was fired in a hot press at 1600° C. for 4 hours under a surface pressure of 200 kgf/cm² in nitrogen using a graphite die 84 patterned with concavities 84a as shown in FIG. 10. The resulting sintered body was re-fired at 1700° C. for 2 hours under a gas pressure of 1500 kgf/cm² in argon by hot isostatic pressing (HIP). Although the mold 84 patterned with the concavities 84a as shown in FIG. 10 was used in this example, a mold 94 patterned with convexities 94a as shown in FIG. 11 may be used as well.

Sandblasting was performed on the resulting sintered body to remove surface deposits, then the sintered body was fixed to a ceramic surface plate, and the surface was flattened by polishing-cloth processing involving diamond abrasive grains to provide an oriented alumina sintered body as an oriented polycrystalline alumina substrate. Other than using this oriented polycrystalline alumina substrate, a light emitting device can be produced in the same manner as Examples 1 and 2.

### Examples of Modifications

In addition to the above-described embodiments, various modifications can be made to the present invention without departing from the gist of the present invention. Examples of such modifications are as follows.
In the case where the substrate 12 is a composite of a base substrate and an oriented polycrystalline alumina layer, the base substrate may be a ceramic sintered body or a metal.
In the case where the substrate 12 is a composite of a base substrate and an oriented polycrystalline alumina layer, the base substrate may be composed of a material that has a thermal expansion coefficient similar or close to those of the materials of the group 13 element nitride crystal layer 14 and the light emitting functional layer 16, and this can prevent or reduce damage to the group 13 element nitride crystal layer 14 and the light emitting functional layer 16 resulting from the difference in thermal expansion coefficient. For example, in the case where the group 13 element nitride crystal layer 14 and the light emitting functional layer 16 are both composed of gallium nitride (GaN), the base substrate may be composed of aluminum nitride (AlN), molybdenum (Mo), tungsten (W), or a combination thereof. This embodiment is suitable for a horizontally-structured light emitting device for which the removal of the substrate 12 is not required.
In the case where the substrate 12 is a composite of a base substrate and an oriented polycrystalline alumina layer, the base substrate may be composed of a material that has a thermal expansion coefficient significantly different from those of the materials of the group 13 element nitride crystal layer 14 and the light emitting functional layer 16, and this facilitates the removal of the substrate 12 from the light emitting functional layer 16 by taking advantage of the difference in thermal expansion coefficient. This embodiment is suitable for a vertically-structured light emitting device for which the removal of the substrate 12 is required.
The light emitting functional layer 16 may be formed by laser CVD and/or lamp-heating CVD.

What is claimed is:

1. A light emitting device, comprising:
a support layer having a surface with a three-dimensional shape, wherein the support layer also functions as a reflective electrode;
a light emitting functional layer formed on the surface with a three-dimensional shape of the support layer, wherein the light emitting functional layer comprises two or more layers composed of semiconductor single crystal grains, wherein each of the two or more layers has a single crystal structure in a direction approximately normal to the surface with a three-dimensional shape; and
a translucent electrode layer provided on a side of the light emitting functional layer opposite to the support layer.

2. The light emitting device according to claim 1, wherein the three-dimensional shape is a curved shape, the light emitting functional layer is formed on an inner circumferential surface of the support layer so that the light emitting device is formed as a curved light emitting device that emits light from an inner circumferential surface side.

3. The light emitting device according to claim 1, wherein the three-dimensional shape is a curved shape, the light emitting functional layer is formed on an outer circumferential surface of the support layer so that the light emitting device is formed as a curved light emitting device that emits light from an outer circumferential surface side.

4. The light emitting device according to claim 1, wherein the three-dimensional shape includes a curved shape and/or a concave-convex shape.

5. The light emitting device according to claim 1, wherein the three-dimensional shape is a macroscopic shape having a visible, three-dimensional profile.

6. The light emitting device according to claim 4, wherein the three-dimensional shape has the concave-convex shape, wherein the difference between the depth of concavities and the height of convexities is 0.05 mm or greater.

7. The light emitting device according to claim 1, wherein a material of the support layer is W or Mo.

8. The light emitting device according to claim 2, further comprising a group 13 element nitride crystal layer or a seed crystal layer between the light emitting functional layer and the translucent electrode layer.

9. The light emitting device according to claim 3, further comprising a group 13 element nitride crystal layer or a seed crystal layer between the light emitting functional layer and the support layer.
